(19) United States
(12) Patent Application Publication
(10) Pub. No.: US 2026/0363142 A1
(43) Pub. Date: Nov. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Min-Shiang Hsu, Kaohsiung City (TW); Yu-Ping Wang, Hsinchu City (TW); Kuei-Chun Hung, Hsinchu City (TW)

(73) Assignee: UNITED MICROELECTRONICS CORP., Hsin-Chu City (TW)

(21) Appl. No.: 19/231,587

(22) Filed: Jun. 9, 2025

(30) Foreign Application Priority Data
May 7, 2025 (TW) 114117132

(51) Int. Cl. H10W 90/00; H10W 20/20; H10W 20/42; H10W 74/10; H10P 54/00; H10W 20/00; H10W 70/60; H10W 70/652; H10W 72/00; H10W 90/10; H10W 90/22

(52) U.S. Cl. CPC H10W 90/00; H10W 20/20; H10W 20/42; H10W 74/137; H10P 54/00; H10W 20/023; H10W 70/60; H10W 70/6528; H10W 72/0198; H10W 90/10; H10W 90/22

(57) ABSTRACT

A method for fabricating a semiconductor device includes the steps of first defining a silicon bridge die region and a spare die region on a substrate, forming a metal interconnection on the silicon bridge die region, forming a through molding via (TMV) on the spare die region, and dicing the substrate to form a first die.

### BACKGROUND OF THE INVENTION

### FIELD OF THE INVENTION

The present invention relates to a method for fabricating semiconductor devices, and more particularly, to an advanced chip packaging integration technique.

### DESCRIPTION OF THE PRIOR ART

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating a semiconductor device includes the steps of first defining a silicon bridge die region and a spare die region on a substrate, forming a metal interconnection on the silicon bridge die region, forming a through molding via (TMV) on the spare die region, and dicing the substrate to form a first die.

According to another aspect of the present invention, a semiconductor device includes a silicon bridge die region and a spare die region on a substrate, a metal interconnection on the silicon bridge die region, and a through molding via (TMVs) on the spare die region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate a method for fabricating a semiconductor device according to an embodiment of the present invention.

FIG. 4 illustrates a structural view of a semiconductor device according to an embodiment of the present invention.

FIG. 5 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

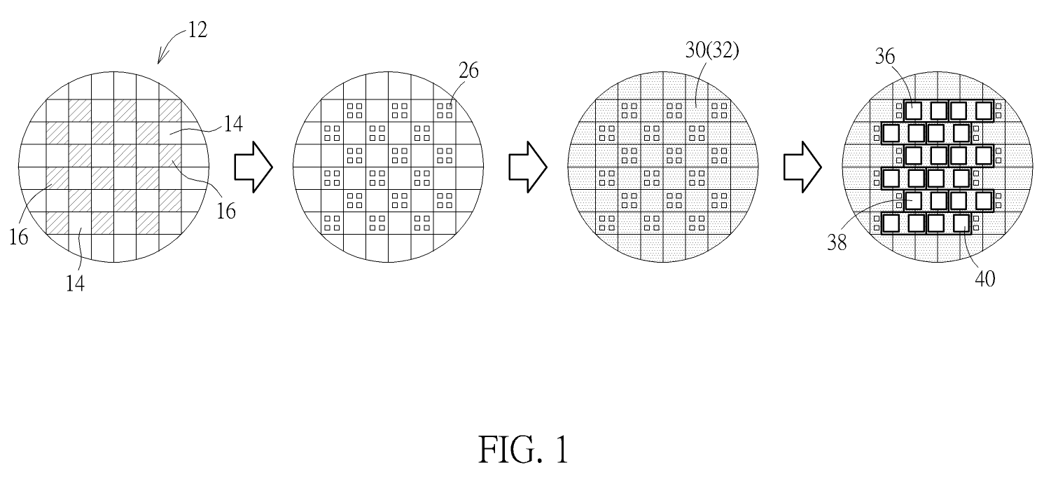

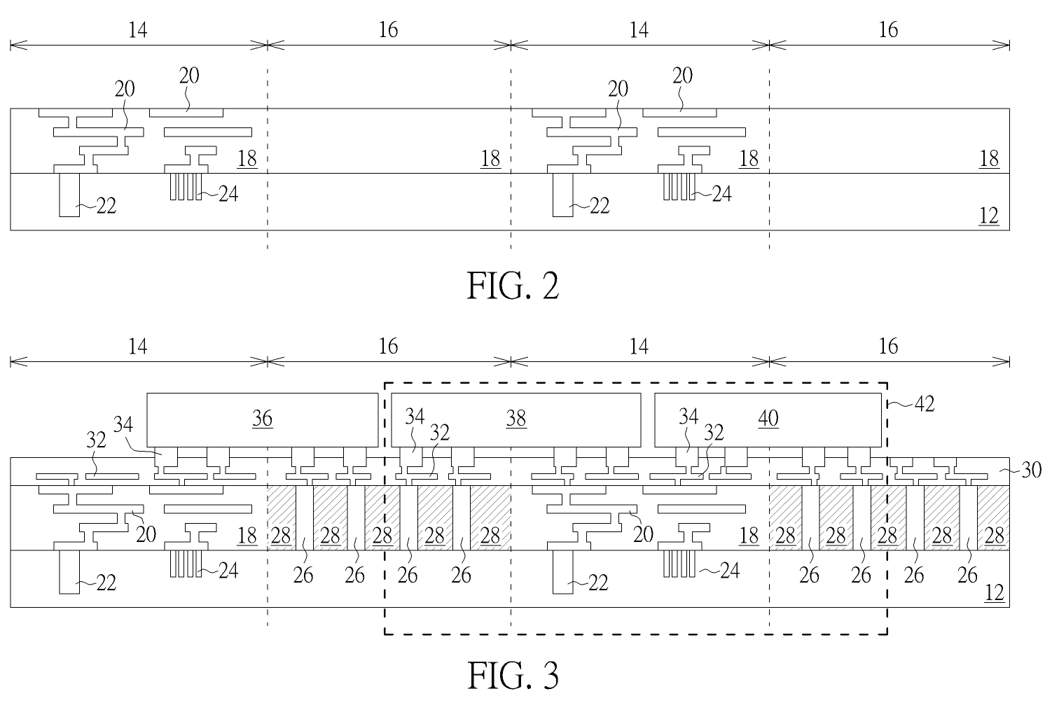

Referring to FIGS. 1-3, which are schematic diagrams illustrating a method for fabricating a semiconductor device according to an embodiment of the present invention, in which FIG. 1 is a top view illustrating the semiconductor device fabrication process of the present embodiment and FIGS. 2-3 are cross-sectional schematic views illustrating the same process. As shown in the first step on the far left of FIGS. 1 and 2, a substrate 12 or an interposer made of a semiconductor material is first provided, in which the substrate 12 includes a silicon wafer formed from a semiconductor material and may be selected from various types of semiconductor substrates such as a silicon substrate, an epitaxial silicon substrate, a silicon carbide substrate, or even a silicon-on-insulator (SOI) substrate. All such material choices are within the scope of the present invention. In this embodiment, the substrate 12 and subsequent substrates or wafers stacked thereon may include dynamic random-access memory (DRAM), although it is not limited thereto. In subsequent process steps, various other devices may also be fabricated, such as medium-voltage (MV) devices, high-voltage (HV) devices, pixel circuits, low-voltage (LV) devices for driving circuits, and/or graphics processing units (GPUs).

Next, at least one and preferably a plurality of silicon bridge die regions 14 and spare die regions 16 are defined on the substrate 12. From a top view perspective, the silicon bridge die regions 14 and the spare die regions 16 are arranged in a checkerboard pattern. It is preferable that during subsequent processing steps, metal interconnect patterns for connecting active or passive components are formed over the silicon bridge die regions 14. In contrast, it is preferable that through molding vias (TMVs) or copper pillars are formed over the spare die regions 16 in later process stages without forming any metal interconnect patterns thereon.

Subsequently, a front-end-of-line (FEOL) process and a back-end-of-line (BEOL) process are performed on the substrate 12, particularly over the aforementioned silicon bridge die regions 14. In this embodiment, the FEOL process may include the formation, depending on process or product requirements, of active devices such as metal-oxide-semiconductor (MOS) transistors, oxide semiconductor field-effect transistors (OS FETs), fin field-effect transistors (FinFETs), or other active components, as well as passive components such as deep trench capacitors (DTCs) 24 on the substrate 12.

The BEOL process may then be used to form metal interconnect structures over these active and/or passive devices, including inter-metal dielectric (IMD) layers 18 and metal interconnections 20. For example, in the case of fabricating a MOS transistor, the FEOL process may include forming a gate structure on the substrate, sidewall spacers (not shown) on the lateral sides of the gate structure, and source/drain regions in the substrate adjacent to the spacers. The gate structure may include polysilicon or metal materials; the sidewall spacers may be made of dielectric materials such as silicon oxide or silicon nitride; and the source/drain regions may include different dopants depending on the conductivity type of the transistor being fabricated, such as P-type or N-type dopants.

Next, an interlayer dielectric (ILD) layer (not shown) may be formed over the substrate 12 to cover the MOS transistors or other active devices. Contact plug formation and BEOL metallization processes are then carried out to form a plurality of contact plugs within the ILD layer electrically connecting the source/drain regions and gate structures. A metal interconnect dielectric layer (IMD) 18 is then formed over the ILD layer and metal interconnections 20 are formed within the IMD layer 18 to connect with the contact plugs. The uppermost metal interconnections 20 may further serve as contact pads for direct bond interconnects (DBIs), which are configured to interface with corresponding DBIs on another wafer during subsequent bonding processes.

In addition, the substrate 12 may further include through-silicon vias (TSVs) 22 formed in accordance with a via-middle process, which electrically connect the metal interconnections 20 to various active and/or passive components on the substrate 12. In this embodiment, the ILD layer and the inter-metal dielectric (IMD) layer 18 may include oxide materials such as, but not limited to, tetraethyl orthosilicate (TEOS). The contact plugs, metal interconnections 20, TSVs 22, and direct bond interconnects (DBIs) may be formed of conductive materials including, but not limited to, aluminum (Al), chromium (Cr), copper (Cu), tantalum (Ta), molybdenum (Mo), tungsten (W), or combinations thereof.

It is noteworthy that, at this stage, it is preferable that the silicon bridge die regions 14 are provided with both the IMD layer 18 and the metal interconnections 20 formed within the IMD layer 18 through the aforementioned FEOL and BEOL processes. In contrast, the spare die regions 16 are formed with only the IMD layer 18 without any metal interconnect patterns therein.

Next, as illustrated in the second step (second from the left) of FIG. 1 and in FIG. 3, the IMD layer 18 over the spare die regions 16 is removed and a plurality of TMVs 26 are formed in the spare die regions 16. A mold sealing layer or molding layer 28 is then formed to surround the TMVs 26. According to one embodiment of the present invention, the formation of the TMVs 26 may be accomplished by removing the IMD layer 18 from the spare die regions 16, forming a dry film such as a patterned resist over the substrate 12 in the spare die regions 16, and then conducting an electroplating process for example to form a plurality of TMVs 26 or copper pillars between the patterned resist structures. The patterned resist may optionally be removed afterward followed by the formation of the molding layer 28 around the TMVs 26.

According to one embodiment of the present invention, the TMVs 26 may include conductive materials such as aluminum (Al), chromium (Cr), copper (Cu), tantalum (Ta), molybdenum (Mo), tungsten (W), or combinations thereof, without being limited thereto. The molding layer 28 could include organic or inorganic material such as oxides of fluorinated silicate glass (FSG). Furthermore, the molding layer 28 may include polymeric materials such as thermosetting polymers, thermoplastic polymers, or mixtures thereof. More specifically, the polymeric materials may include plastic materials, epoxy resins, polyimide, polyethylene terephthalate (PET), polyvinyl chloride (PVC), polymethyl methacrylate (PMMA), polymers doped with specific fillers, or combinations thereof.

Next, as illustrated in the third step (third from the left) of FIG. 1 and in FIG. 3, a contact pad formation process is carried out. A dielectric layer 30 is formed over the IMD layer 18 of the silicon bridge die regions 14 and the molding layer 28 of the spare die regions 16. A redistribution layer (RDL) 32 is then formed within the dielectric layer 30, followed by the formation of bumps 34 such as micro-bumps or solder balls on top of the redistribution layer 32. In this embodiment, the dielectric layer 30 may include an organic material layer based on polyimide. The redistribution layer 32 and the bumps 34 may be composed of materials such as aluminum (Al), copper (Cu), silver (Ag), gold (Au), nickel (Ni), tungsten (W), or alloys thereof, but are not limited thereto. It is important to note that, at this stage, the substrate 12 remains in the form of a complete wafer, i.e., it has not yet been singulated into individual dies.

Next, as illustrated in the fourth step (far right) of FIG. 1 and in FIG. 3, a plurality of dies 36, 38, and 40 each having different functionalities and obtained through a wafer singulation process, are bonded to the silicon bridge die regions 14 and the spare die regions 16 of the substrate 12. The dies 36, 38, and 40 may include, for example, system-on-chip (SoC) dies and may be connected to the substrate 12 or wafer using micro-bumps 34 or direct bond interconnects (DBIs) depending on product design or specification requirements. In this embodiment, the dies 36, 38, and 40 may include high bandwidth memory (HBM) dies, radio frequency integrated circuit (RFIC) dies, power amplifier (PA) dies, or high electron mobility transistor (HEMT) dies based on group III-V compound semiconductors such as gallium nitride (GaN), but are not limited thereto.

Next, a dicing process may be performed, as shown by the finer and/or thicker dashed lines in FIG. 3 to singulate the substrate 12 or wafer into a plurality of dies 42 or stacked structures based on process or product requirements. According to a preferred embodiment of the present invention, at least one or a portion of the diced dies or stacked structures preferably includes at least one silicon bridge die region 14 and at least one spare die region 16, in which the silicon bridge die region 14 includes metal interconnect patterns formed by metal interconnections 20 while the spare die region 16 is provided with a plurality of TMVs 26 and a molding layer 28. Preferably, no metal interconnect patterns embedded within the IMD layer 18 are formed in the spare die region 16. In other words, each die 42 or stacked structure may simultaneously include multiple distinct regions composed of metal interconnections 20 and/or TMVs 26. These different regions may be electrically connected to a single system-on-chip (SoC) die such as die 38, and the arrangement of these regions may alternate or repeat in sequence. All such configurations are within the scope of the present invention.

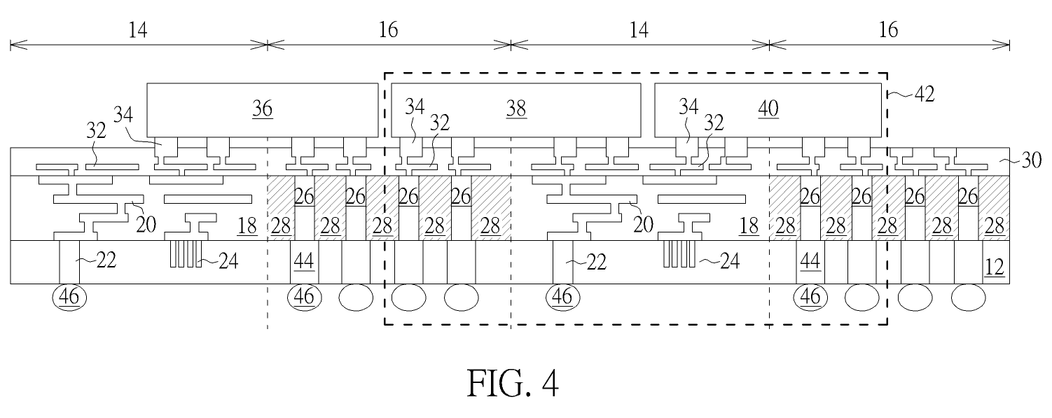

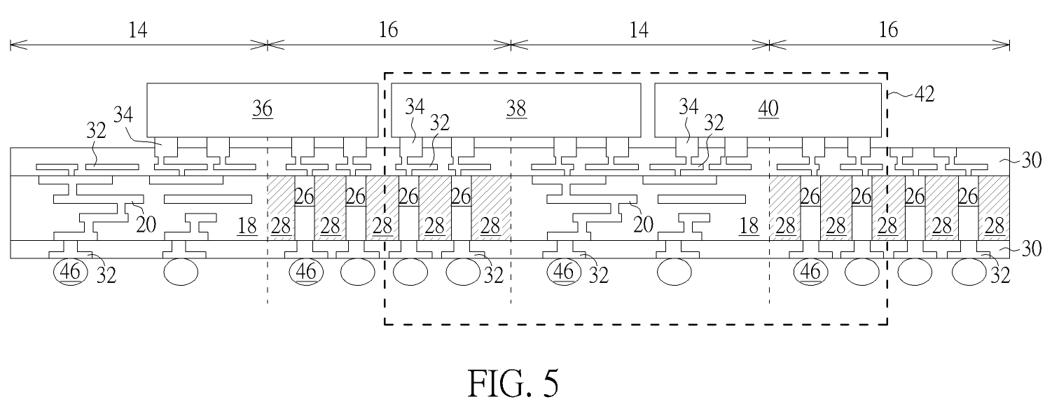

Referring to FIG. 4, which is a schematic diagram illustrating the structure of a semiconductor device according to an embodiment of the present invention. As shown in FIG. 4, in contrast to the embodiment depicted in FIG. 3 where TSVs 22 are formed only within the substrate 12 of the silicon bridge die region 14 via a via-middle process, the present invention further allows for an alternative approach. Specifically, TSVs 22 may first be formed in the silicon bridge die region 14 using a via-middle process, followed by a grinding process to partially thin the substrate 12 and expose the TSVs 22 from the backside of the silicon bridge die region 14. Subsequently, additional TSVs 44 may be formed within the substrate 12 of the spare die region 16 using a via-last process such that they directly connect to the previously formed TMVs 26. Thereafter, bumps 46 such as solder balls may be formed to connect the exposed TSVs 22 and 44. In this embodiment, the TSVs 22 and 44 in the silicon bridge die region 14 and the spare die region 16, respectively, may be composed of the same or different materials. The width of the TSVs 44 in the spare die region 16 may be slightly larger than or equal to the width of the TMVs 26. The TSVs 22 and 44 may be formed from conductive materials such as aluminum, chromium, copper, tantalum, molybdenum, tungsten, or combinations thereof, without being limited thereto.

Referring to FIG. 5, which illustrates a structural schematic of a semiconductor device according to an embodiment of the present invention. As shown in FIG. 5, in contrast to the embodiment in FIG. 3 where based on a silicon substrate, the redistribution layer (RDL) 32 is formed only on one side of the substrate 12 (e.g., the top/front side), the present invention further allows when a non-silicon material is used for the substrate 12, for RDLs 32 to be simultaneously formed on both the front and back sides of the substrate 12. These dual-sided RDLs may provide electrical connections to the metal interconnection 20 and/or TMVs 26 located in different regions of the device. For example, the present invention may involve forming a dielectric layer 30, an RDL 32, and bumps 34 on the front side of the substrate 12 for connection to a system-on-chip (SoC). A grinding process may then be performed to thin the substrate 12 and expose the IMD layer 18 of the silicon bridge die region 14 and the molding layer 28 of the spare die region 16 from the backside. Subsequently, dielectric layer 30, RDL 32, and bumps 46 may also be formed on the backside, specifically on the bottom surfaces of the IMD layer 18 and the molding layer 28. In this configuration, the RDL 32 on the silicon bridge die region 14 preferably connects to the metal interconnection 20 whereas the RDL 32 on the spare die region 16 connects to the TMVs 26. As in the previously described embodiments, the dielectric layer 30 may include an organic material layer based on polyimide. The RDLs 32 and bumps 46 may be formed from materials such as aluminum (Al), copper (Cu), silver (Ag), gold (Au), nickel (Ni), tungsten (W), or alloys thereof, without being limited thereto.

In summary, the present invention discloses a novel chip packaging process, which primarily involves first defining at least one silicon bridge die region and at least one spare die region on a substrate or silicon wafer. Metal interconnections are then formed in the silicon bridge die region while TMVs are formed in the spare die region and the substrate is subsequently singulated to form a plurality of dies. Compared to conventional processes which typically involve first dicing a blank wafer into individual dies, mounting the dies onto a carrier wafer, and then performing subsequent processes such as metal interconnect formation, TMV formation, and redistribution layer (RDL) fabrication on each individual die, the packaging technique of the present invention as performed in the described sequence offers several advantages including a significant reduction in defect rates, effective simplification of process complexity, and overall savings in manufacturing costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
defining a silicon bridge die region and a spare die region on a substrate;
forming a metal interconnection on the silicon bridge die region;
forming a through molding via (TMV) on the spare die region; and
dicing the substrate to form a first die.

2. The method of claim 1, further comprising:
forming an inter-metal dielectric (IMD) layer on the substrate;
forming the metal interconnection in the IMD layer;
removing the IMD layer on the spare die region;
forming a molding layer on the spare die region; and
forming the TMV in the molding layer.

3. The method of claim 1, further comprising:
forming a through-silicon via (TSV) in the substrate for connecting the metal interconnection; and
forming a bump for connecting the TSV.

4. The method of claim 1, further comprising:
forming a through-silicon via (TSV) in the substrate for connecting the TMV; and
forming a bump for connecting the TSV.

5. The method of claim 1, further comprising forming a second die for connecting the metal interconnection and the TMV.

6. The method of claim 1, wherein the substrate comprises a silicon wafer.

7. The method of claim 1, further comprising:
forming an organic layer on the substrate; and
forming a redistribution layer in the organic layer.

8. A semiconductor device, comprising:
a silicon bridge die region and a spare die region on a substrate
a metal interconnection on the silicon bridge die region; and
a through molding via (TMV) on the spare die region.

9. The semiconductor device of claim 8, further comprising:
an inter-metal dielectric (IMD) layer around the metal interconnection on the silicon bridge die region;
a molding layer around the TMV on the spare die region.

10. The semiconductor device of claim 8, further comprising:
a through-silicon via (TSV) in the substrate for connecting the metal interconnection; and
a bump connected to the TSV.

11. The semiconductor device of claim 8, further comprising:
a through-silicon via (TSV) in the substrate for connecting the TMV; and
a bump connected to the TSV.

12. The semiconductor device of claim 8, further comprising a die connected to the TMV and the metal interconnection.

13. The semiconductor device of claim 8, wherein the substrate comprises a silicon wafer.

14. The semiconductor device of claim 8, further comprising:
an organic layer on the substrate; and
a redistribution layer in the organic layer.
